(19) United States
(12) Patent Application Publication
(10) Pub. No.: US 2014/0265996 A1
(43) Pub. Date: Sep. 18, 2014

(54) Solar Folder

(71) Applicant: Derek Djeu, New York, NY (US)

(72) Inventor: Derek Djeu, New York, NY (US)

(21) Appl. No.: 13/799,214

(22) Filed: Mar. 13, 2013

(51) Int. Cl. H01L 31/045; H02J 7/02

(52) U.S. Cl. CPC H01L 31/045; H02J 7/025
USPC 320/101; 136/245

(57) ABSTRACT

The subject matter disclosed herein relates to a solar folder. In one particular example, a solar folder comprises a solar module integrated into the side of a solar case. The solar module comprises solar cells mounted on a circuit board with power conditioning and monitoring integrated circuits, which are laminated between two sheets of polymers. The edges of the solar module are sewn with thread into side of the solar case. The solar case has a stiff flap that attaches at the bend of the solar case. The flap can be flipped to be on either side of the solar case. The flap can also be bent to form triangle support structure to prop up the solar case at a fixed tilt angle. The device can be charged wirelessly by induction through induction charging coils in the circuit board that support and integrate the solar cells.

### CROSS-REFERENCE TO RELATED APPLICATIONS

This application claims the benefit of the following five U.S. Provisional Patent Applications Nos. 61/615,303 filed Mar. 25, 2012, 61/636,221 filed Apr. 20, 2012, 61/654,855 filed Jun. 2, 2012, 61/696,290 filed Sep. 3, 2012, 61/669,291 filed Sep. 11, 2012, 61/713,517 filed Oct. 13, 2012 and 61/735,064 filed Dec. 10, 2012 by the present inventor. These provisional patent applications are incorporated herein by reference.

### BACKGROUND OF THE DISCLOSURE

The solar PV industry has been developing and growing, with expanding markets, lowering costs and higher-efficiency products. Solar PV cells appear in consumer electronics, such as watches and calculators. Solar PV modules appear on rooftops and large utility-scale projects. The applications for solar PV and generating electric power directly from the sun continue to grow.

At the same time personal electronics and gadgets have become more ubiquitous. Cell phones, smart phones, tablets, electronic readers and digital cameras are often carried with individuals throughout the day, whether to work, for leisure activities, for camping or for emergency purposes.

### SUMMARY OF THE DISCLOSURE

This invention is a novel concept for a solar folder that serves also as a personal solar module to charge these personal electronics devices and also to carry the electronics devices as well as other belongings in the cavity of the solar case. The invention is also novel in that the solar module is comprised of solar cells that are mounted on a circuit board that not only provides a mechanical support for the cells but also provides power conditioning, monitoring and energy storage through integrated circuits connected and mounted on the circuit board. Another innovative aspect of the solar case is that a flap attached at the bend of the solar case can be used to form a truss structure that can be used to angle the integrated solar module toward the light source. The truss structure can also be used to hold the solar case open at a certain angle so that the user can prop up a device between the flap and the solar case at an angle. A light or illuminated icon on the solar module will flash at a rate that is proportional to the electrical current that is being generated by the solar module, in order to indicate to the user the speed of charging, and allow user to optimize orientation of the solar module. The flap can also be used to cover the solar cells. One other innovative aspect of the invention is that the circuit board has inductive charging coils, that allow the user to charge a device without cords. The user could place the device on either side of the circuit board and solar cells to charge the device.

### BRIEF DESCRIPTION OF THE DRAWINGS

FIGS. 1a through 1c illustrate three perspective views of the first embodiment of the present invention.

FIG. 2 illustrates a perspective view of the first embodiment of the present invention with the flap partially opened.

FIGS. 3a and 3b illustrates two perspective views of the first embodiment of the present invention with the flap positioned in a closed and a standing position respectively.

FIG. 4 illustrates a perspective of the first embodiment of the present invention with a battery and electronics device added.

FIG. 5 illustrates a perspective of the first embodiment of the present invention with the electronics device and papers installed.

FIG. 6 shows the composition of the solar module of the first embodiment of the present invention with the main components broken out.

FIG. 7 illustrated an exploded view of the solar module of the first embodiment of the present invention with the main components broken out with additional detail on the location of the induction charging coils.

FIG. 8 shows a cross-sectional view of the solar module of the first embodiment of the present invention.

FIGS. 9 through 12 illustrate cross-sectional views of the solar module of second, third, fourth and fifth embodiments of the present invention.

FIG. 13 shows a flow diagram of the communication of data from the solar case to the Internet and online database for publishing.

FIG. 14 illustrates a perspective view of the first embodiment with various components illustrated.

### LIST OF NUMERALS

Part No/Part name
1 solar case
1a front side
1b back side
1c periphery
2 solar module
3 solar cell
6 electronics device
7 Velcro area
8 Velcro tabs
9 battery
10 front sheet
11 thread
13 circuit board
14 back sheet
15 bypass diodes
16 integrated circuits
17 conductors
17a papers
18 encapsulant adhesive
20 adhesive
21 USB connector
22 heating elements
27 bendable flap
27a flap bottom part
27b flap top part
27c flap bend
28 pinch
30 zipper
31a first fastener
31b second fastener
31c third fastener
31d fourth fastener
33 back exterior
34 tab
35 illuminated icon
36 induction charging coils
37 top edge
40 first wire
41 second wire
42 electrical tabs
43 electrical vias
100 solar folder

### DETAILED DESCRIPTION OF THE DISCLOSURE

FIGS. 1a through 8 illustrate the first embodiment of the current invention. The following discussion, with reference to the figures, describes the invention in detail. FIGS. 1a through 1c illustrate three perspective views of solar folder 100. The solar folder 100 is comprised of solar module 2 and solar case 1. The solar module 2 is integrated into one side of the solar case 1, the solar case having a front side 1a and a back side 1b, back side 1b having a back exterior 33, facing away from the solar module. FIG. 1a illustrates solar case 1 in a standing position. Both front side 1a and back side 1b have a periphery 1c (only front side 1a periphery is shown in FIG. 1a), which extends around the perimeter of back side 1b and front side and extends from the edge about ½ inch. The perimeter of the solar module is sewn into the solar case material with a thread stitch 11. The solar module 2 contains solar cells 3. The other side of solar case 1 can be zipped to the side with solar module 2 to form a cavity for storing items. A bendable flap 27 is attached to the solar case 1 at the bend between the two sides. Bendable flap 27 is constructed with two equal parts; a flap bottom part 27a, a flap top part 27b, the two parts connected with a bend 27c. The light, LED or illuminated icon 35 flashes at a rate proportional to the electrical current that the solar module is producing. This allows the user to optimize the orientation of the solar module. First fasteners 31a are attached to front side 1a. Referring now to FIG. 1b, electronics device 6 is secured to the side of the solar case with the solar module with Velcro tabs 8 on a Velcro area 7. Referring now to FIG. 1c, the solar case 1 is opened with the electronics device 6 completely exposed and the solar case 1 propped up by the bent flap 27.

FIG. 2 illustrates a perspective view of the solar folder 100 with solar case 1 shown with bendable flap 27. The two sides of solar case 1 are zipped together with zipper 30. Bendable flap 27 is positioned over the front side 1a of the solar case to cover, conceal and protect the solar cells. The bendable flap 27 can be flipped to the back side of the solar case 1 to expose the solar module 2 to light.

FIGS. 3a and 3b illustrate perspective views of solar case 1 and bendable flap 27. In FIG. 3a, bendable flap 27 lies flat over the solar module to conceal it. In FIG. 3b, solar case 1 has a front side 1a and a back side 1b. In FIG. 3b, bendable flap 27 is bent to form a triangle support structure for solar case 1 so it is in a standable position to face a light source. Solar case 1 can then be opened to expose electronics device at a fixed tilt angle for use. In this way, electronics device 6 can be propped up in a standing position, at an angle for the user to view the device screen. Also illustrated in FIG. 3b is the top edge 37 of flap top part 27b inserted under tab 34 to secure the bendable flap 27 in place. There are multiple tabs 34 so that the bendable flap can be secured at different angles in order to optimally tilt the solar module 2 toward a light source.

FIG. 4 shows a perspective view of solar case 1 electrically connected to an electronics device 6. Solar case 1 electrically charges the electronics devices 6, such as cell phones, tablets or smart phones or other electronics, with power from solar module 2. A power conditioning device or a battery 9 may electrically interface between solar case 1 and electronics device 6 using first wire 40 and second wire 41. The solar case can be used to carry other belongings such as papers 17a.

FIG. 5 shows a perspective view of solar case 1 with electronics device 6, resting on top of the solar cells, never covering any complete solar cell, and being charged by induction. Solar case 1 electrically charges the electronics devices 6, such as cell phones, tablets or smart phones or other electronics, with power from the solar module. Electronics device 6 can charge without cables by induction charging through the induction charging coils on the circuit board that also supports and integrates the solar cells.

FIGS. 6 and 7 illustrate the composition of solar module 2 with the main components broken out. A front sheet 10, constructed out of a rigid or flexible transparent material such as Plexiglas, glass or clear polymers is laminated or adhered on the top of solar cells 3. Front sheet 10 can be attached to solar cells 3 with an adhesive such as EVA, PVB, silicone, or other clear adhesives. Solar cells 3 can also be rigid or flexible and are front contact, which means that there are electrical busbars on the top of the cell. Back contact solar cells can also be used. Solar cells 3 are mounted and soldered on front side of a circuit board 13, made from a lightweight hard material such as Garolite or other pre-impregnated materials. Bypass diodes 15 are mounted and soldered on back side of circuit board 13 to be electrically connected to solar cells 3. Other power conditioning and monitoring integrated circuits 16 are mounted and soldered on the back of the circuit board. A back sheet 14 is laminated to the back of circuit board 13. Front sheet 10 and back sheet 14 extend beyond the edges of circuit board 13 so that their perimeters meet and are laminated together. The areas of the front sheet 10 and back sheet 14 that extend beyond the circuit board can be stitched with a thread 11 to the solar case material.

FIG. 7 further illustrates the composition of solar module 2 with the main components broken out with additional detail on the location of the induction charging coils 36 on the printed circuit board. The induction charging coils are placed centered between solar cells, so that when the device is placed on top of solar module 2 there is a reduced chance that any single cell will be completely covered and so that the induction charging field can pass through in the gap between the cells. A completely covered solar cell would block the current flowing through solar module 2. Electronics device 6 can be charged by induction on either side of solar module 2.

FIG. 8 shows a cross-sectional view of solar module 2, the cross section taken as shown in FIG. 2. Solar cells 3 are electrically interconnected in series by conductors 17 such as tinned copper strips, along the cell busbars. The conductors 17 on bottom of solar cells 3 are soldered to the top of circuit board 13, and bypass diodes 15 are also soldered to the bottom of the circuit board and electrically connected in parallel with the solar cell through the circuit board by electrical vias 43 which pass through the circuit board 13. Other power conditioning and monitoring integrated circuits 16 are soldered to the bottom of the circuit board and can provide power conditioning and energy storage to electrically charge the electronics devices 6. An encapsulant adhesive 18, such as silicone, EVA or another adhesive, fills the area between the front sheet 10 and the back sheet 14. The perimeter of the solar module, beyond the edges of the circuit board is stitched with thread 11 to attach the solar module to the solar case material (thread not shown in the figure).

FIG. 9 shows a cross-sectional view of a second embodiment of solar module 2. Solar cells 3 have a layer of adhesive 20, such as silicone or EVA or another adhesive, between circuit board 13 and the solar cell 3.

FIG. 10 shows a cross-sectional view of a third embodiment of solar module 2. In this configuration, a USB connector 21 is attached to the back of circuit board 13 and protrudes through the back sheet 14. The USB connector 21 provides an electrical plug or interface between solar module 2 and electronics device 6.

FIG. 11 shows a cross-sectional view of a fourth embodiment of solar module 2. In this configuration, a battery 9 or energy storage device is attached or pressed to the back of circuit board 13 and is electrically connected with solar module 2. There are resistors or heating elements 22 between battery 9 and circuit board 13. The resistors or heating elements are soldered directly to the printed circuit board and are used to heat the battery above zero degrees Celsius or within the operating temperature of the battery. The resistors or heating elements can be powered directly by solar cells 3 or by battery 9. In this embodiment, the printed circuit board forms the back of the solar module. Holes are drilled around the edge of the circuit board 13 to stitch a thread linking the circuit board 13 and the fabric of the front side of the solar case.

FIG. 12 shows a cross-sectional view of a fifth embodiment of solar module 2. In this configuration, a back contact solar cell is attached to the top of the circuit board 13 by electrical tabs 42 on the back of the solar cell.

FIG. 13 shows a flow diagram of the communication of data from solar module 2 to the Internet and online database for publishing. Solar module 2 has integrated circuits that monitor the voltage and current of the solar module and that send the data to electronics device 6 via a cable or wirelessly. The electronics device then connects to the Internet and can upload the data to an online database for publishing. The online database could exist on a separate data server or a social media service such as Twitter, Facebook or an online sharing site. The recorded data would include the quantity of energy produced by solar module 2 with a time stamp over periods of time. The energy data would be recorded at a central online location, and the user could earn renewable energy credits from the energy produced by the solar module 2.

FIG. 14 shows solar folder 100 with solar case 1 configured in a standing position with back exterior 33 and bendable flap 27. Bendable flap 27 joins solar case 1 at pinch 28 between the front side 1a of solar case 1 with solar module 2 and the back side 1b of solar case 1. A zipper 30 closes solar case 1 to form a cavity. Second fasteners 31b are attached to flap top part 27b, that is positioned so that it is attachable to first fasteners 31a (see FIG. 1a) when bendable flap is positioned to be closed as illustrated in FIG. 2. Third fasteners 31c are attached to flap top part 27b on the inside, and fourth fasteners 31d are attached to back side 1b so that when bendable flap is straightened and placed against back side 1b, it will be secured there. In the first embodiment, the fasteners used are a hook and loop pair. However in alternate embodiments, fasteners such as snaps, magnets, and other types of fasteners may be used.

1. An apparatus, said apparatus capable of interfacing with an energy storage device and an electronics device, said apparatus comprising
a solar module, said solar module comprising:
a circuit board, said circuit board having edges;
a plurality of solar cells mounted directly onto said circuit board;
integrated circuits connected to each of said plurality of solar cells, said integrated circuits capable of providing power conditioning and monitoring of said plurality of solar cells;
a first sheet of polymer and a second sheet of polymer, said circuit board being laminated between said first sheet of polymer and said second sheet of polymer, wherein said first sheet of polymer is positioned on top of said plurality of solar cells, said first sheet of polymer and said second sheet of polymer extend beyond said edges of said circuit board and are attached to each other beyond said edges;
a solar case; said solar case is comprised of:
a bendable flap, said bendable flap is comprised of:
a first part of said bendable flap;
a second part of said bendable flap; said second part having a top edge;
a flap bend;
at least one first fastener and at least one second fastener;
a back side, and a front side, said back side and said front side having a periphery, said back side having a back exterior; said back side having at least one tab positioned on said back exterior, said at least one tab being slightly raised from said back side so that said at least one tab can catch said top edge of said bendable flap;
said back side additionally comprised of a first zipper component, said first zipper component attached to said periphery of said back side;
said front side additionally comprised of a second zipper component, said second zipper component attached to said periphery of said front side where said first zipper component and said second zipper component are a matched zipper pair,
said front side is attachable to said solar module.

2. The apparatus of claim 1, wherein said integrated circuits on said circuit board are capable of monitoring and recording power and energy that is generated by said solar module and transfer this data to said electronics device for storage and publishing to an online database.

3. The apparatus of claim 1, wherein said circuit board has induction charging coils capable of charging said electronics device.

4. The apparatus of claim 1, wherein said energy storage device is a battery.

5. The apparatus of claim 1, wherein said circuit board has a part selected from the group consisting of resistors, heating elements and a combination thereof, said part positioned between said energy storage device and said circuit board.

6. The apparatus of claim 1, wherein said bendable flap can be positioned to lie flat against said front side and said back side.

7. The apparatus of claim 1, wherein said solar case has a means for securing said electronics device to said inside of said solar case.

8. The apparatus of claim 7, wherein said means for securing said electronics device to said inside of said solar case is comprised of hook and loop components.

9. The apparatus of claim 1, wherein said at least one tab on said back side is capable of securing said top edge of said bendable flap to said at least one tab, thereby permitting said solar case to be configured in a standing position.

10. The apparatus of claim 1 wherein said back side and said front side are secured to each other at said periphery.

11. The apparatus of claim 10 wherein said solar module and said front side are secured to each other using thread.

12. The apparatus of claim 1 where said at least one first fastener and said at least one second fastener belong to the group consisting of hook and loop fasteners, snap fasteners, and magnets.

13. The apparatus of claim 1 wherein:
said solar module being capable of connecting with said energy storage device; and
said electronics device being capable of connecting to said energy storage device.

14. The apparatus of claim 1 wherein an illuminated icon positioned on said solar module blinks at a frequency proportional to said power.

15. An apparatus, said apparatus capable of interfacing with an energy storage device and an electronics device, said apparatus comprising
a solar module, said solar module comprising:
a circuit board, said circuit board having edges;
a plurality of solar cells mounted directly onto said circuit board;
integrated circuits connected to each of said plurality of solar cells, said integrated circuits capable of providing power conditioning and monitoring of said plurality of solar cells;
a first sheet of polymer, said circuit board being attached said first sheet of polymer, wherein said first sheet of polymer is positioned on top of said plurality of solar cells, said first sheet of polymer extends beyond said edges of said circuit board;
a solar case; said solar case is comprised of:
a bendable flap, said bendable flap is comprised of:
a first part of said bendable flap;
a second part of said bendable flap; said second part of said having a top edge;
a flap bend
at least one first fastener and at least one second fastener;
a back side, and a front side, said back side and said front side having a periphery, said back side having a back exterior, at least one tab positioned on said back exterior, said at least one tab being slightly raised from said back side so that said at least one tab can catch said top edge of said bendable flap;
said back side additionally comprised of a first zipper component, said first zipper component attached to said periphery of said back side;
said front side additionally comprised of a second zipper component, said second zipper component attached to said periphery of said front side where said first zipper component and said second zipper component are a matched zipper pair,
said front side is attachable to said solar module.
